(19) United States
(12) Patent Application Publication
(10) Pub. No.: US 2025/0172968 A1
(43) Pub. Date: May 29, 2025

(54) FLEXIBLE DISPLAY SCREEN AND ELECTRONIC DEVICE

(71) Applicant: VIVO MOBILE COMMUNICATION CO., LTD., Dongguan (CN)

(72) Inventor: Zipeng SU, Dongguan (CN)

(73) Assignee: VIVO MOBILE COMMUNICATION CO., LTD., Dongguan (CN)

(21) Appl. No.: 19/034,549

(22) Filed: Jan. 22, 2025

Related U.S. Application Data
(63) Continuation of application No. PCT/CN2023/108902, filed on Jul. 24, 2023.

(30) Foreign Application Priority Data
Jul. 28, 2022 (CN) 202210898882.2

(51) Int. Cl. G06F 1/16; H10H 29/39; H10H 29/856

(52) U.S. Cl. CPC G06F 1/1652; H10H 29/39; H10H 29/856

(57) ABSTRACT

This application provides a flexible display screen and an electronic device. The flexible display screen includes a first film layer, a second film layer, a third film layer, and a connecting piece. The first film layer, the second film layer, and the third film layer are stacked, the third film layer is disposed between the first film layer and the second film layer. The first film layer is provided with a first connecting hole. The second film layer is provided with a second connecting hole. The third film layer is provided with a third connecting hole. The first connecting hole, the second connecting hole, and the third connecting hole communicate with each other. The connecting piece is filled in the first connecting hole, the second connecting hole, and the third connecting hole to connect the first film layer, the second film layer, and the third film layer.

### CROSS-REFERENCE TO RELATED APPLICATIONS

This application is a continuation of International Application No. PCT/CN 2023/108902, filed on Jul. 24, 2023, which claims priority to Chinese Patent Application No. 202210898882.2, filed on Jul. 28, 2022. The entire contents of each of the above-referenced applications are expressly incorporated herein by reference.

### TECHNICAL FIELD

This application relates to the field of communications technologies, and specifically, to a flexible display screen and an electronic device.

### BACKGROUND

With the development of communications technology, electronic devices including flexible display screens such as foldable displays or rollable displays appearing on the market have been favored by many users. When a display of the electronic device switches between different states, better visual impact can be brought to the user, for example, when playing a game, browsing information, watching a movie, or having other behaviors, the user can have better use experience, and it is easy for the user to carry.

However, the flexible display screen usually has a multi-layer structure. As a result, the flexible display screen is prone to delamination during folding and curling, which further causes a display defect such as a black spot on the flexible display screen, and even causes damage to the flexible display screen.

### SUMMARY

Embodiments of this application are intended to provide a flexible display screen and an electronic device.

This application is implemented as follows.

According to a first aspect, an embodiment of this application provides a flexible display screen, including a first film layer, a second film layer, a third film layer, and a connecting piece, where the first film layer, the second film layer, and the third film layer are stacked, the first film layer is provided with a first connecting hole, the second film layer is provided with a second connecting hole, the third film layer is provided with a third connecting hole, the first connecting hole, the second connecting hole, and the third connecting hole communicate with each other, the connecting piece is filled in the first connecting hole, the second connecting hole, and the third connecting hole to connect the first film layer, the second film layer, and the third film layer, and the connecting piece includes an organic material.

According to a second aspect, an embodiment of this application further provides an electronic device, including the foregoing flexible display screen.

In the embodiments of this application, during folding or curling of the flexible display screen, the first connecting hole, the second connecting hole, and the third connecting hole are disposed to disperse force on the flexible display screen after the flexible display screen is bent, and disperse overall force on the flexible display screen to local points, and the connecting piece is disposed to improve adhesive force between the various structural layers of the flexible display screen. Therefore, a bending resistance capability of the flexible display screen is improved, delamination of the flexible display screen is avoided during folding and curling, and a display defect such as a black spot on the flexible display screen is further avoided, to improve a display effect of the flexible display screen and prevent damage to the flexible display screen.

### BRIEF DESCRIPTION OF DRAWINGS

FIG. 1 is a schematic diagram of a circuit structure of a flexible display screen according to an embodiment of this application;

FIG. 2 is a partial schematic diagram of a P2 structure in FIG. 1;

FIG. 3 is a sectional view of a flexible display screen according to an embodiment of this application;

FIG. 4 is a partial schematic diagram of a flexible display screen according to an embodiment of this application;

FIG. 5 is a sectional view of a flexible display screen according to another embodiment of this application;

FIG. 6 is a partial schematic diagram of a flexible display screen according to another embodiment of this application;

FIG. 7 is a sectional view of a flexible display screen according to another embodiment of this application;

FIG. 8 is a partial schematic diagram of a flexible display screen according to another embodiment of this application;

FIG. 9 is a partial schematic diagram of a flexible display screen according to another embodiment of this application;

FIG. 10 is a partial schematic diagram of a flexible display screen according to another embodiment of this application;

FIG. 11 and FIG. 12 are schematic diagrams of structures in a case that an electronic device is in different states according to an embodiment of this application; and

FIG. 13 to FIG. 15 are schematic diagrams of structures in a case that an electronic device is in different states according to another embodiment of this application.

DESCRIPTIONS OF REFERENCE NUMERALS
100: flexible display screen, 101: outer surface, 102: inner surface, 110: first film layer, 120: second film layer, 130: connecting piece, 131: transverse connection part, 132: longitudinal connection part, 140: drive layer, 141: thin film transistor, 150: first light-emitting layer, 160: second light-emitting layer, 170: first package layer, 180: light blocking structure, 181: first light blocking part, 182: second light blocking part, 190: third film layer, 210: first touch layer, 220: support substrate, 230: second touch layer, 240: cover plate, 241: first cover plate, 242: second cover plate, 260: first optical adhesive layer, 270: second optical adhesive layer, and 280: polarizer; and
300: device body, and 310: stylus holder.

### DETAILED DESCRIPTION

The following describes technical solutions in the embodiments of this application with reference to the accompanying drawings in the embodiments of this application. Apparently, the described embodiments are some but not all of the embodiments of this application. All other embodiments obtained by a person of ordinary skill in the art based on the embodiments of this application without creative efforts shall fall within the protection scope of this application.

The terms “first”, “second”, and the like in this specification and claims of this application are used to distinguish between similar objects instead of describing a specific order or sequence. It should be understood that terms used in such a way are interchangeable in proper circumstances, so that the embodiments of this application can be implemented in an order other than the order illustrated or described herein. Objects classified by “first”, “second”, and the like are usually of a same type, and a quantity of objects is not limited. For example, there may be one or more first objects. In addition, in this specification and the claims, “and/or” indicates at least one of connected objects, and a character “/” generally indicates an “or” relationship between associated objects.

With reference to the accompanying drawings, a flexible display screen and an electronic device provided in the embodiments of this application are described below in detail by using specific embodiments and application scenarios thereof.

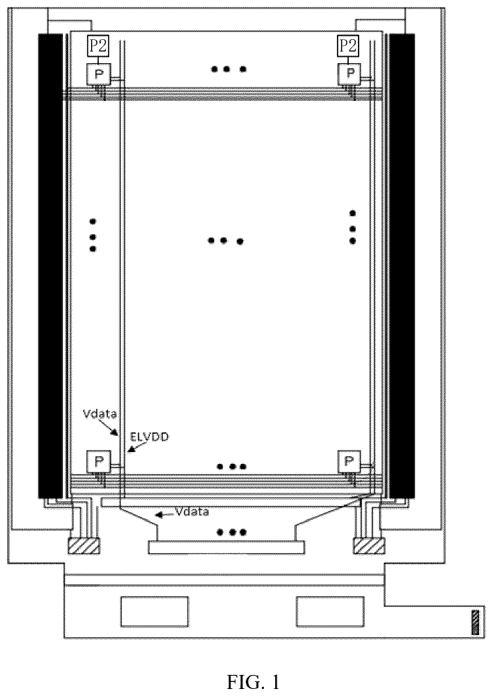

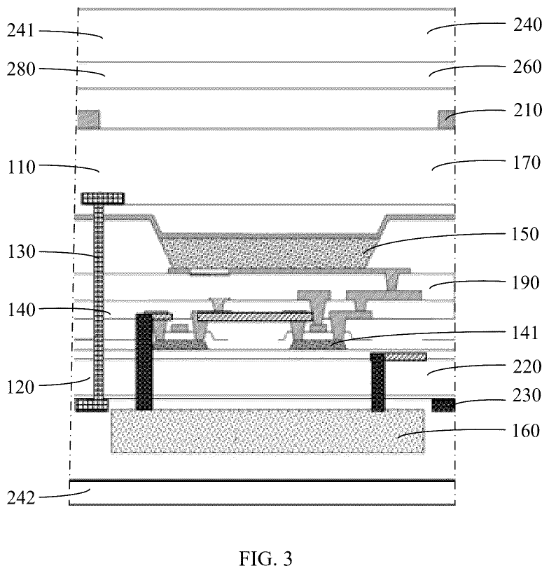

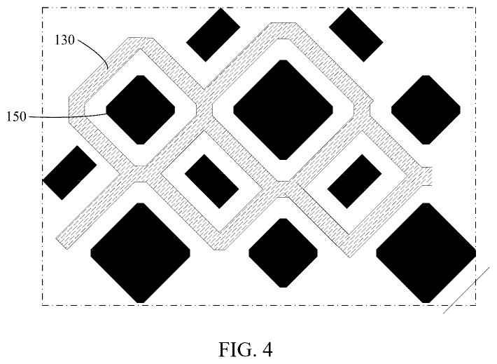

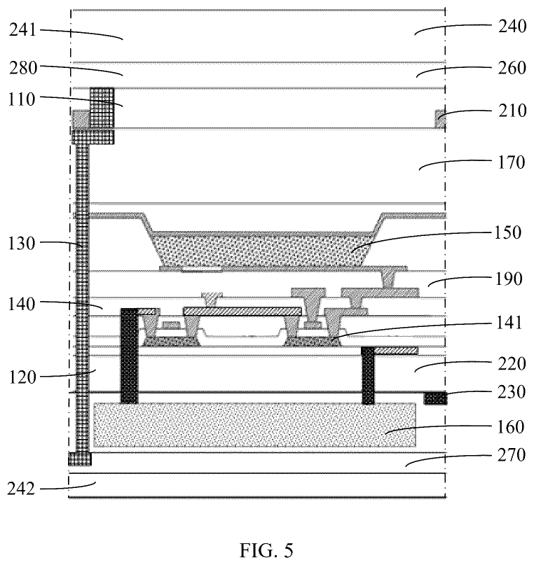

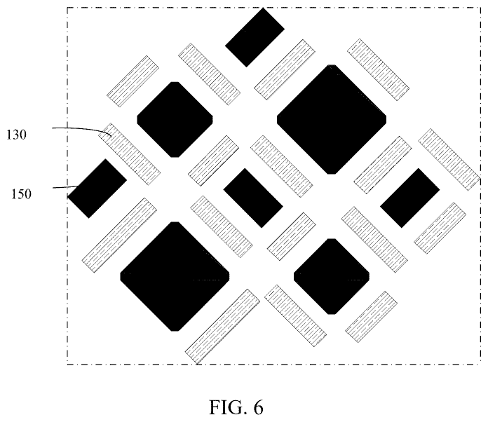

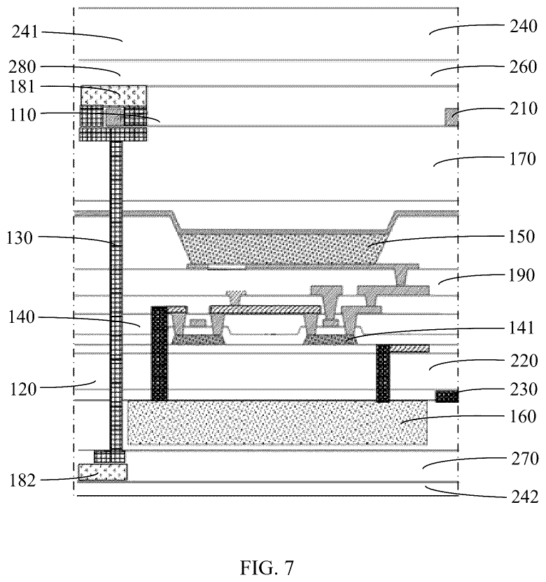

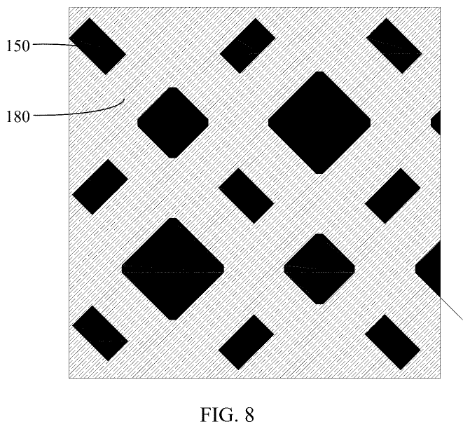

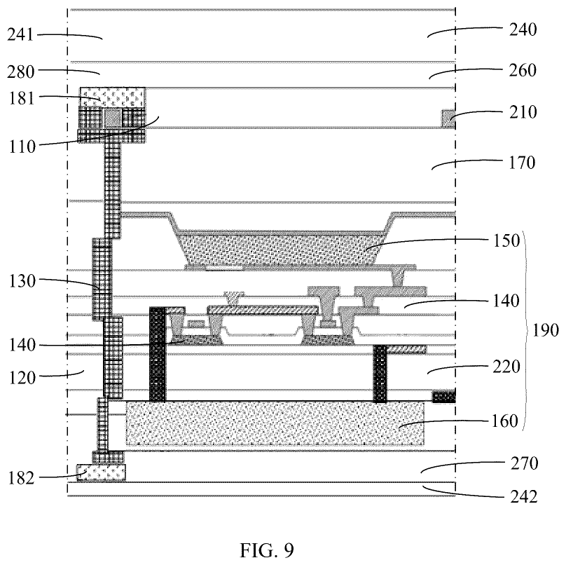

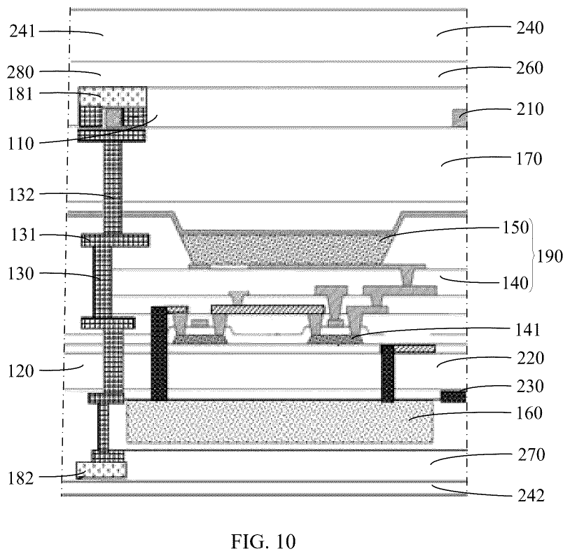

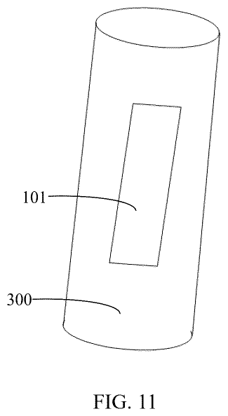

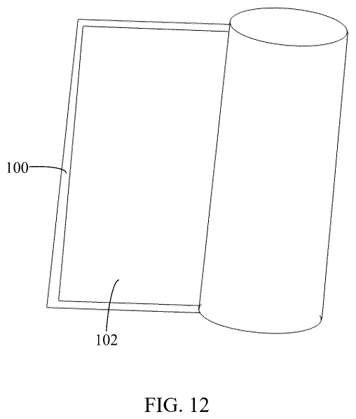

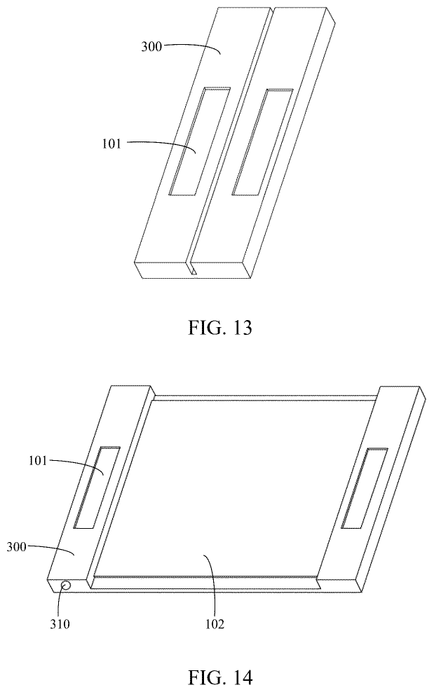

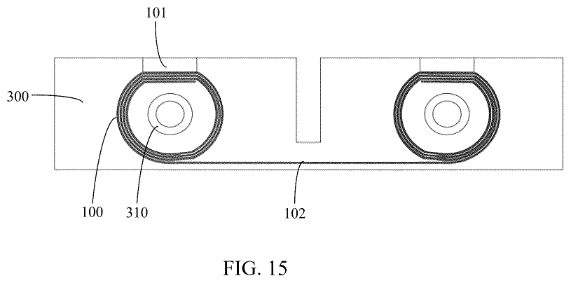

As shown in FIG. 1 to FIG. 15, an embodiment of this application discloses a flexible display screen, including a first film layer 110, a second film layer 120, a third film layer 190, and a connecting piece 130, where the first film layer 110, the second film layer 120, and the third film layer 190 are stacked, the third film layer 190 is disposed between the first film layer 110 and the second film layer 120, the first film layer 110 is provided with a first connecting hole, the second film layer 120 is provided with a second connecting hole, the third film layer is provided with a third connecting hole, the first connecting hole, the second connecting hole, and the third connecting hole communicate with each other, the connecting piece 130 is filled in the first connecting hole, the second connecting hole, and the third connecting hole to connect the first film layer 110, the second film layer 120, and the third film layer 190, and the connecting piece 130 includes an organic material. For example, the organic material may be a plastic resin material, polyimide, a polyester material, polycarbonate, polyethylene, or the like, which is not specifically limited in this embodiment of this application. During folding or curling of the flexible display screen, the first connecting hole, the second connecting hole, and the third connecting hole are disposed to disperse force on the flexible display screen after the flexible display screen is bent, and disperse overall force on the flexible display screen to local points, and the connecting piece 130 is disposed to improve adhesive force between the various structural layers of the flexible display screen. Therefore, a bending resistance capability of the flexible display screen is improved, delamination of the flexible display screen is avoided during folding and curling, and a display defect such as a black spot on the flexible display screen is further avoided, to improve a display effect of the flexible display screen.

It should be noted that the connecting piece 130 may be of a flexible structure, to prevent the connecting piece 130 from causing obstruction to bending of the flexible display screen.

For example, there is a certain gap between the connecting piece 130 and an inner wall of the first connecting hole, between the connecting piece 130 and an inner wall of the second connecting hole, and between the connecting piece 130 and an inner wall of the third connecting hole, and the gap can further disperse force on the flexible display screen after the flexible display screen is bent. Moreover, the gap can provide deformation space for the first film layer 110, the second film layer 120, and the third film layer 190. For example, the connecting piece 130 is in close contact with the inner wall of the first connecting hole, the inner wall of the second connecting hole, and the inner wall of the third connecting hole, to more reliably prevent delamination of the flexible display screen.

In an optional embodiment, the third film layer 190 includes a drive layer 140, the drive layer 140 includes a plurality of thin film transistors 141 arranged at an interval, and two ends of the connecting piece 130 respectively extend to two opposite sides of the thin film transistor 141 in a thickness direction of the flexible display screen, so that the connecting piece 130 connects more structural layers, and a plurality of structural layers of the flexible display screen are bound and connected, to further improve an effect of preventing delamination of the flexible display screen and extend a service life of the flexible display screen.

In an optional embodiment, the first film layer 110 is a support substrate 220, and the support substrate 220 is a base member of the flexible display screen and can provide an arrangement basis for other structural layers of the flexible display screen. The drive layer 140 is disposed on the support substrate 220, the second film layer 120 is a first package layer 170 disposed on the support substrate 220 or a first optical adhesive layer 260 disposed on the first package layer 170, and the third film layer 190 includes the drive layer 140 and a first light-emitting layer 150, that is, the flexible display screen may be a single-sided display. The first light-emitting layer 150 is disposed on the drive layer 140, the first package layer 170 is disposed on the first light-emitting layer 150, and the first package layer 170 is located on a side of the first light-emitting layer 150 away from the drive layer 140, configured to isolate external water and oxygen, to protect the first light-emitting layer 150. Because the first package layer 170 needs to ensure sufficient packaging effects, a structural strength of the first package layer is high, and the connecting piece 130 is connected to the first package layer 170, to further improve the effect of preventing delamination of the flexible display screen. For example, the first package layer 170 may be an organic package layer, or may be formed by disposing an organic package layer and an inorganic package layer alternately. This is not specifically limited herein.

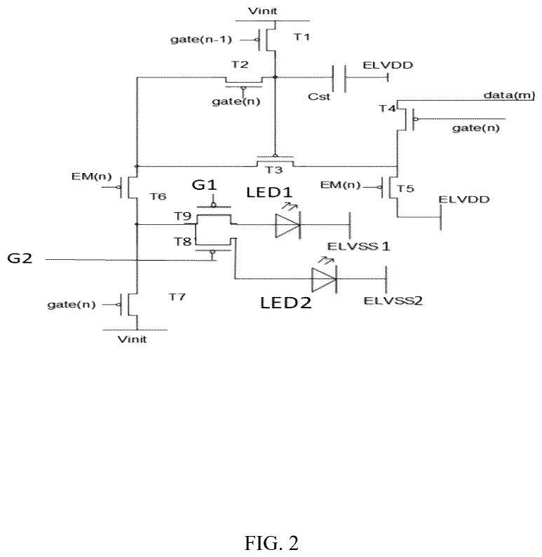

In another optional embodiment, the flexible display screen is a double-sided display, and is formed by adding a light-emitting pixel to another side of the single-sided display, as shown in FIG. 2, for example, including addition of an LED2, a thin film transistor T8, and a control switch line G2, and the control switch line G2 is electrically connected to a thin film transistor T2. The flexible display screen further includes a support substrate 220, a drive layer 140, a first light-emitting layer 150, and a second light-emitting layer 160, and the support substrate 220 is a base member of the flexible display screen and can provide an arrangement basis for other structural layers of the flexible display screen. The drive layer 140 is disposed on the support substrate 220. For example, the support substrate 220 may be made of a flexible material such as polyimide. This is not specifically limited herein. The drive layer 140 includes a plurality of thin film transistors 141 arranged at an interval, the first light-emitting layer 150 and the second light-emitting layer 160 are disposed on two opposite sides of the support substrate 220, the second light-emitting layer 160 is disposed on a side of the support substrate 220 away from the drive layer 140, a positive electrode and a negative electrode of the second light-emitting layer 160 are electrically connected to the drive layer 140 through the support substrate 220 separately, the first light-emitting layer 150 is disposed on a side of the drive layer 140 away from the support substrate 220, and the first light-emitting layer 150 is electrically connected to the drive layer 140. That is, the first light-emitting layer 150 and the second light-emitting layer 160 are respectively connected to the thin film transistors 141 of the drive layer 140, and the drive layer 140 can drive the first light-emitting layer 150 to work separately, can drive the second light-emitting layer 160 to work separately, and can also drive the first light-emitting layer 150 and the second light-emitting layer 160 to work simultaneously. The first light-emitting layer 150 and the second light-emitting layer 160 in the solution share the same drive layer 140, which is conducive to reducing a thickness of the flexible display screen. For example, the first light-emitting layer 150 and the second light-emitting layer 160 may correspond to different drive layers 140 respectively, to separately control the first light-emitting layer 150 and the second light-emitting layer 160 to work. This is not specifically limited in this embodiment of this application. The first film layer 110 and the second film layer 120 are located on two opposite sides of the support substrate 220. Because the support substrate 220 is usually made of an inorganic material and is not easy to break, the connecting piece 130 is connected to the support substrate 220, which can further improve the effect of preventing delamination of the flexible display screen, to improve the display effect of the flexible display screen and extend the service life of the flexible display screen.

In a further optional embodiment, the first film layer 110 is a first package layer 170 disposed on a side of the support substrate 220 or a first optical adhesive layer 260 disposed on the first package layer 170, the second film layer 120 is a second package layer disposed on another side of the support substrate 220 or a second optical adhesive layer 270 disposed on a side of the second package layer away from the support substrate 220, the second package layer is configured to isolate the external water and oxygen to protect the second light-emitting layer 160, and the third film layer 190 includes the support substrate 220, the drive layer 140, the first light-emitting layer 150, and the second light-emitting layer 160. In this case, the connecting piece 130 passes through a plurality of structural layers of the flexible display screen, and the plurality of structural layers are bound and connected, which can effectively prevent slipping and loosening of the structural layers to improve the display effect of the flexible display screen. It should be noted that the third film layer 190 may further include a planarization layer, an insulating layer, and the like, so that the connecting piece 130 can connect more structural layers.

In a further optional embodiment, the first film layer 110 is a first touch layer 210 disposed on a side of the first package layer 170 away from the drive layer 140, and the second film layer 120 is a second touch layer 230 disposed on a side of the support substrate 220 away from the first touch layer 210. In this case, more structural layers of the flexible display screen are bound and connected by using the connecting piece 130, and connection firmness of the connecting piece 130 is better, to further avoid delamination of the flexible display screen during folding and curling, and extend the service life of the flexible display screen.

In another optional embodiment, a hole diameter of the third connecting hole is smaller than a hole diameter of the first connecting hole, and the hole diameter of the third connecting hole is smaller than a hole diameter of the second connecting hole. The first connecting hole, the second connecting hole, and the third connecting hole extend in the thickness direction of the flexible display screen, and the first connecting hole and the second connecting hole are provided at two ends of the third connecting hole respectively, that is, the first connecting hole, the third connecting hole, and the second connecting hole form a I-shaped structure, so that diameters of connecting pieces 130 filled in the first connecting hole, the second connecting hole, and the third connecting hole are different, and diameters of connecting pieces 130 in the first connecting hole and the second connecting hole are greater than a diameter of a connecting piece 130 in the third connecting hole. Therefore, connection performance of the connecting pieces 130 of this structure is more reliable.

In still another optional embodiment, the flexible display screen further includes a cover plate 240, the cover plate 240 is located on an outermost side of the flexible display screen, and the cover plate 240 is configured to protect an internal structure of the flexible display screen. For example, the cover plate 240 may be of a flexible transparent structure. For example, an end of the connecting piece 130 near the cover plate 240 is provided with a light blocking structure 180, and the light blocking structure 180 is connected to an end surface of the connecting piece 130. In the thickness direction of the flexible display screen, an orthographic projection of the light blocking structure 180 covers an orthographic projection of the connecting piece 130. The light blocking structure 180 is configured to block reflected light emitted by a touch metal wire and another metal wire of the flexible display screen, to increase display brightness of the flexible display screen and improve the display effect of the flexible display screen. For example, the light blocking structure 180 may be disposed on a side of the connecting piece 130, and the light blocking structure 180 may be a non-reflective micro-particle material such as carbon black or a black dye material such as aniline black. For example, the light blocking structure 180 may be another structure with light blocking performance. This is not specifically limited in this embodiment of this application. It should be noted that the light blocking structure 180 may be disposed to replace a polarizer, to increase the brightness of the flexible display screen.

In another optional embodiment, an end portion of the connecting piece 130 includes a light blocking material, that is, the light blocking structure 180 and the connecting piece 130 are of an integrated structure to facilitate disposing of the connecting piece 130. The light blocking material is configured to block reflected light emitted by a touch metal wire and another metal wire of the flexible display screen, to increase display brightness of the flexible display screen and improve the display effect of the flexible display screen.

In an embodiment in which the flexible display screen is a double-sided display, the cover plate 240 includes a first cover plate 241 and a second cover plate 242, the first cover plate 241 is disposed opposite the second cover plate 242, and the first cover plate 241 and the second cover plate 242 are separately located on the outermost side of the flexible display screen, to protect the internal structure of the flexible display screen. The light blocking structure 180 may include a first light blocking part 181 and a second light blocking part 182, and the first light blocking part 181, the connecting piece 130, and the second light blocking part 182 are sequentially arranged in the thickness direction of the flexible display screen, that is, in the thickness direction of the flexible display screen, the first light blocking part 181 and the second light blocking part 182 are disposed at two ends of the connecting piece 130 respectively, to strengthen a light blocking effect of the light blocking structure 180 and improve the display effect of the flexible display screen.

In an embodiment in which the first film layer 110 is the first optical adhesive layer 260 disposed on the first package layer 170 and the second film layer 120 is the second optical adhesive layer 270 disposed on the side of the second package layer away from the support substrate 220, the first cover plate 241 and the second cover plate 242 are connected to the first optical adhesive layer 260 and the second optical adhesive layer 270 respectively, and the first optical adhesive layer 260 and the second optical adhesive layer 270 have light-admitting quality to meet display performance of the flexible display screen.

For example, the flexible display screen further includes a polarizer 280, the polarizer 280 may be disposed at the same layer as the first optical adhesive layer 260, to reduce the thickness of the flexible display screen. For example, the polarizer 280 may be disposed at different layers from the first optical adhesive layer 260. This is not specifically limited in this embodiment of this application.

In still another optional embodiment, the third film layer 190 includes a first film sublayer and a second film sublayer, the third connecting hole includes a first through hole provided on the first film sublayer and a second through hole provided on the second film sublayer, the first through hole and the second through hole communicate with each other, and an orthographic projection of the first through hole on a plane on which the first film layer is located partially overlaps an orthographic projection of the second through hole on the plane on which the first film layer is located, so that the first through hole and the second through hole are misaligned. In this case, the connecting piece 130 may be of a bent structure, which can effectively prevent the structural layers of the flexible display screen from slipping and loosening, and can prevent the connecting piece 130 from moving in the thickness direction of the flexible display screen during folding or curling of the flexible display screen, to strengthen a connection effect of the connecting piece 130 and further improve connection stability between the structural layers of the flexible display screen.

For example, there are at least two first through holes and at least two second through holes, and the first through holes and the second through holes are alternately arranged in the thickness direction of the flexible display screen, to increase a quantity of times of bending the connecting piece 130 and further improve connection stability of the connecting piece 130.

In yet another optional embodiment, the third film layer 190 includes a first film sublayer and a second film sublayer, the third connecting hole includes a first through hole provided on the first film sublayer and a second through hole provided on the second film sublayer, the first through hole and the second through hole communicate with each other, and a part of the connecting piece 130 located in the first through hole includes a transverse connection part 131 and a longitudinal connection part 132. In the thickness direction of the flexible display screen, an orthographic projection of the longitudinal connection part 132 is in an orthographic projection of the transverse connection part 131, that is, when the flexible display screen is unfolded, a size of the longitudinal connection part 132 in a direction parallel to the flexible display screen is greater than a size of the transverse connection part 131 in the direction parallel to the flexible display screen. Therefore, the transverse connection part 131 and the longitudinal connection part 132 extend in different directions, and the connecting piece 130 has a better connection effect. For example, the longitudinal connection part 132 may follow the thickness direction of the flexible display screen, and the longitudinal connection part 132 and the transverse connection part 131 are disposed vertically to facilitate manufacture of the flexible display screen.

In an embodiment, in a case that there are at least two first through holes and at least two second through holes, the transverse connection part 131 and the longitudinal connection part 132 are alternately arranged in the thickness direction of the flexible display screen, to improve connection stability of the connecting piece 130. In a case that there are at least two longitudinal connection parts 132, the longitudinal connection parts 132 are alternately arranged, that is, in the thickness direction of the flexible display screen, parts of the longitudinal connection parts 132 overlap, and the other parts do not overlap. Each longitudinal connection part 132 is located between two transverse connection parts 131, so that a film layer between the two transverse connection parts 131 can be provided with a connecting hole of an equal section size. Therefore, the flexible display screen is easier to process.

In an optional embodiment, a reflective structure is disposed in the connecting piece 130, so that the connecting piece 130 has a function of reflecting light and can reflect light emitted by a light-emitting component of the flexible display screen to the outside of the flexible display screen, to increase a light utilization rate of the flexible display screen and improve light-emitting brightness of the flexible display screen. In addition, the reflective structure of the connecting piece 130 can reduce power consumption of the flexible display screen and delay attenuation of an organic light-emitting material, to increase the service life of the flexible display screen. For example, the connecting piece 130 may be made of a material with reflective performance, or a coating with a reflective effect may be applied to an outer surface of the connecting piece 130. This is not specifically limited in this embodiment of this application.

In another optional embodiment, the connecting piece 130 includes an organic material doped with a reflective particle, the doped reflective particle may be a white titanium dioxide micro-particle, or a mixed or separate micro-particle of silicon dioxide, calcium oxide, sodium oxide, titanium dioxide, barium oxide, and the like, and a shape of the micro-particle may be a sphere, a square, a plate, a strip, or the like. For example, a length of the micro-particle may range from 1 nm to 1000 nm. In some embodiments, the length of the micro-particle may range from 50 nm to 100 nm. For example, the length of the micro-particle may be selected according to actual requirements. This is not specifically limited herein.

In an embodiment in which the flexible display screen includes the first light-emitting layer 150 and the second light-emitting layer 160, the connecting piece 130 may separately reflect a part of light emitted by the first light-emitting layer 150 and a part of light emitted by the second light-emitting layer 160 to the outside of the flexible display screen, to reduce a loss of the light emitted by the first light-emitting layer 150 and the light emitted by the second light-emitting layer 160 and further increase light-emitting brightness of the flexible display screen.

In an optional embodiment, the flexible display screen has a plurality of pixel areas, and at least two connecting pieces 130 are disposed at an interval in a circumferential direction of a same pixel area, there is a gap between connecting pieces 130, and during folding or curling of the flexible display screen, the gap can provide deformation space for the connecting pieces 130, to avoid deformation of the connecting piece 130 due to excessive extrusion, and extend the service life of the flexible display screen. In another optional embodiment, at least one connecting piece 130 is an annular connecting piece, and the annular connecting piece surrounds at least one pixel area. In this case, the connecting piece 130 is of an integrated structure with better stability. Correspondingly, the connecting piece 130 can better connect the structural layers of the flexible display screen, to improve overall stability of the flexible display screen.

Based on the flexible display screen disclosed in the embodiments of this application, an embodiment of this application further discloses an electronic device including the flexible display screen described in any one of the foregoing embodiments.

For example, the electronic device may be a foldable-display electronic device or a rollable-display electronic device. This is not specifically limited in this embodiment of this application.

In an optional embodiment, the electronic device includes a flexible display screen 100 and a device body 300, the flexible display screen 100 is disposed on the device body 300, and the flexible display screen 100 is located in the device body 300 in a case of the flexible display screen 100 in a contracted state, to protect the flexible display screen 100. For example, the flexible display screen 100 has an outer surface 101 and an inner surface 102, and may perform display only on the outer surface 101, or perform display only on the inner surface 102, or perform display on the inner surface 102 and the outer surface 101 simultaneously. This is not specifically limited herein. For example, the device body 300 is provided with a stylus holder 310 to accommodate a stylus.

The embodiments of this application are described above with reference to the accompanying drawings, but this application is not limited to the foregoing specific implementations, and the foregoing specific implementations are only illustrative and not restrictive. Under the enlightenment of this application, a person of ordinary skill in the art can make many forms without departing from the purpose of this application and the protection scope of the claims, all of which fall within the protection of this application.

1. A flexible display screen, comprising a first film layer, a second film layer, a third film layer, and a connecting piece, wherein the first film layer, the second film layer, and the third film layer are stacked, the third film layer is disposed between the first film layer and the second film layer, the first film layer is provided with a first connecting hole, the second film layer is provided with a second connecting hole, the third film layer is provided with a third connecting hole, the first connecting hole, the second connecting hole, and the third connecting hole communicate with each other, the connecting piece is filled in the first connecting hole, the second connecting hole, and the third connecting hole to connect the first film layer, the second film layer, and the third film layer, and the connecting piece comprises an organic material.

2. The flexible display screen according to claim 1, wherein the third film layer comprises a drive layer, the drive layer comprises a plurality of thin film transistors arranged at an interval, and two ends of the connecting piece respectively extend to two opposite sides of the thin film transistor in a thickness direction of the flexible display screen.

3. The flexible display screen according to claim 2, wherein the first film layer is a support substrate, the second film layer is a first package layer disposed on the support substrate or a first optical adhesive layer disposed on the first package layer, the third film layer comprises the drive layer and a first light-emitting layer, the drive layer is disposed on the support substrate, the first light-emitting layer is disposed on the drive layer, and the first package layer is disposed on the first light-emitting layer.

4. The flexible display screen according to claim 1, wherein the flexible display screen is a double-sided display, the flexible display screen further comprises a support substrate, a drive layer, a first light-emitting layer, and a second light-emitting layer, the drive layer is disposed on the support substrate, the drive layer comprises a plurality of thin film transistors arranged at an interval, the first light-emitting layer and the second light-emitting layer are disposed on two opposite sides of the support substrate, and the first film layer and the second film layer are located on two opposite sides of the support substrate.

5. The flexible display screen according to claim 4, wherein the first film layer is a first package layer disposed on a side of the support substrate or a first optical adhesive layer disposed on the first package layer, the second film layer is a second package layer disposed on another side of the support substrate or a second optical adhesive layer disposed on a side of the second package layer away from the support substrate, the third film layer comprises the support substrate, the drive layer, the first light-emitting layer, and the second light-emitting layer.

6. The flexible display screen according to claim 1, wherein a hole diameter of the third connecting hole is smaller than a hole diameter of the first connecting hole, and the hole diameter of the third connecting hole is smaller than a hole diameter of the second connecting hole.

7. The flexible display screen according to claim 1, wherein the flexible display screen further comprises a cover plate, an end of the connecting piece near the cover plate is provided with a light blocking structure, and the light blocking structure is connected to an end surface of the connecting piece, or an end portion of the connecting piece comprises a light blocking material.

8. The flexible display screen according to claim 1, wherein the third film layer comprises a first film sublayer and a second film sublayer, the third connecting hole comprises a first through hole provided on the first film sublayer and a second through hole provided on the second film sublayer, the first through hole and the second through hole communicate with each other, and an orthographic projection of the first through hole on a plane on which the first film layer is located partially overlaps an orthographic projection of the second through hole on the plane on which the first film layer is located, so that the first through hole and the second through hole are misaligned.

9. The flexible display screen according to claim 1, wherein the third film layer comprises a first film sublayer and a second film sublayer, the third connecting hole comprises a first through hole provided on the first film sublayer and a second through hole provided on the second film sublayer, the first through hole and the second through hole communicate with each other, and a part of the connecting piece located in the first through hole comprises a transverse connection part and a longitudinal connection part.

10. The flexible display screen according to claim 1, wherein a reflective structure is disposed in the connecting piece; or
the connecting piece comprises an organic material doped with a reflective particle.

11. The flexible display screen according to claim 1, wherein the flexible display screen has a plurality of pixel areas, and at least two connecting pieces are disposed at an interval in a circumferential direction of a same pixel area; or
at least one connecting piece is an annular connecting piece, and the annular connecting piece surrounds at least one pixel area.

12. An electronic device, comprising a flexible display screen, wherein the flexible display screen comprises a first film layer, a second film layer, a third film layer, and a connecting piece, wherein the first film layer, the second film layer, and the third film layer are stacked, the third film layer is disposed between the first film layer and the second film layer, the first film layer is provided with a first connecting hole, the second film layer is provided with a second connecting hole, the third film layer is provided with a third connecting hole, the first connecting hole, the second connecting hole, and the third connecting hole communicate with each other, the connecting piece is filled in the first connecting hole, the second connecting hole, and the third connecting hole to connect the first film layer, the second film layer, and the third film layer, and the connecting piece comprises an organic material.

13. The electronic device according to claim 12, wherein the third film layer comprises a drive layer, the drive layer comprises a plurality of thin film transistors arranged at an interval, and two ends of the connecting piece respectively extend to two opposite sides of the thin film transistor in a thickness direction of the flexible display screen.

14. The electronic device according to claim 13, wherein the first film layer is a support substrate, the second film layer is a first package layer disposed on the support substrate or a first optical adhesive layer disposed on the first package layer, the third film layer comprises the drive layer and a first light-emitting layer, the drive layer is disposed on the support substrate, the first light-emitting layer is disposed on the drive layer, and the first package layer is disposed on the first light-emitting layer.

15. The electronic device according to claim 12, wherein the flexible display screen is a double-sided display, the flexible display screen further comprises a support substrate, a drive layer, a first light-emitting layer, and a second light-emitting layer, the drive layer is disposed on the support substrate, the drive layer comprises a plurality of thin film transistors arranged at an interval, the first light-emitting layer and the second light-emitting layer are disposed on two opposite sides of the support substrate, and the first film layer and the second film layer are located on two opposite sides of the support substrate.

16. The electronic device according to claim 15, wherein the first film layer is a first package layer disposed on a side of the support substrate or a first optical adhesive layer disposed on the first package layer, the second film layer is a second package layer disposed on another side of the support substrate or a second optical adhesive layer disposed on a side of the second package layer away from the support substrate, the third film layer comprises the support substrate, the drive layer, the first light-emitting layer, and the second light-emitting layer.

17. The electronic device according to claim 12, wherein a hole diameter of the third connecting hole is smaller than a hole diameter of the first connecting hole, and the hole diameter of the third connecting hole is smaller than a hole diameter of the second connecting hole.

18. The electronic device according to claim 12, wherein the flexible display screen further comprises a cover plate, an end of the connecting piece near the cover plate is provided with a light blocking structure, and the light blocking structure is connected to an end surface of the connecting piece, or an end portion of the connecting piece comprises a light blocking material.

19. The electronic device according to claim 12, wherein the third film layer comprises a first film sublayer and a second film sublayer, the third connecting hole comprises a first through hole provided on the first film sublayer and a second through hole provided on the second film sublayer, the first through hole and the second through hole communicate with each other, and an orthographic projection of the first through hole on a plane on which the first film layer is located partially overlaps an orthographic projection of the second through hole on the plane on which the first film layer is located, so that the first through hole and the second through hole are misaligned.

20. The electronic device according to claim 12, wherein the third film layer comprises a first film sublayer and a second film sublayer, the third connecting hole comprises a first through hole provided on the first film sublayer and a second through hole provided on the second film sublayer, the first through hole and the second through hole communicate with each other, and a part of the connecting piece located in the first through hole comprises a transverse connection part and a longitudinal connection part.
